(19) United States
(12) Patent Application Publication
(10) Pub. No.: US 2015/0263033 A1
(43) Pub. Date: Sep. 17, 2015

(54) Semiconductor Device and Manufacturing Method Thereof

(71) Applicant: Kabushiki Kaisha Toshiba, Tokyo (JP)

(72) Inventor: Tomonori AOYAMA, Yokkaichi (JP)

(21) Appl. No.: 14/482,285

(22) Filed: Sep. 10, 2014

(30) Foreign Application Priority Data
Mar. 12, 2014 (JP) 2014-049303

(51) Int. Cl. H01L 27/115; H01L 21/02

(52) U.S. Cl. CPC H01L 27/11582; H01L 27/11556; H01L 21/02645; H01L 21/02667; H01L 21/02532; H01L 21/0262; H01L 21/02592

(57) ABSTRACT

In a manufacturing method of a semiconductor device according to an embodiment, a stacked structure constituted by an electrode, an insulation film, and an amorphous thin film is formed. A microwave of a first frequency is irradiated to the stacked structure so as to selectively heat the electrode. Thereby a seed crystal is formed in a part of the amorphous thin film adjacent to the electrode. A microwave of a second frequency that is different from the first frequency is irradiated to the stacked structure so as to grow the seed crystal. Thereby a polycrystalline thin film is formed.

### CROSS REFERENCE TO RELATED APPLICATION(S)

This application is based upon and claims the benefit of priority from the prior Japanese Patent Application No. 2014-049303, filed on Mar. 12, 2014, the entire contents of which are incorporated herein by reference.

### FIELD

Embodiments described herein relate generally to a semiconductor device and a manufacturing method thereof.

### BACKGROUND

In recent years, in memory devices having a three-dimensional stacked structure (hereinafter, “three-dimensional memories”), a polycrystalline silicon (Si) thin film is used as a channel film. To give a smooth surface morphology to a polycrystalline Si thin film and to improve coatability of processes with a polycrystalline Si thin film, amorphous Si is generally used at the time of stacking. That is, a polycrystalline Si thin film is formed by forming an amorphous Si thin film and crystallizing amorphous Si by thermal processing.

However, according to a conventional method of forming a polycrystalline Si thin film, formed Si crystals have a small grain diameter, so that there is a problem that the channel carrier mobility is low. For example, when an amorphous Si thin film having a film thickness of 4 to 10 nm is subjected to thermally processing at 950° C. for an hour, the grain diameter of Si crystals is approximately 10 nm.

As a method of increasing the grain diameter of Si crystals, there has been proposed a method of crystallizing amorphous Si by microwave annealing. However, in such a conventional method, a seed crystal that is the core of the growth of a Si crystal is randomly formed in an amorphous Si thin film, so that the position of a grain boundary between Si crystals formed by growing seed crystals cannot be controlled. As a result, there has been a problem that there is a variation in a threshold voltage between a transistor having a grain boundary in a channel and a transistor not having a grain boundary in a channel.

### BRIEF DESCRIPTION OF THE DRAWINGS

FIG. 1 is a cross-sectional view showing a schematic configuration of a semiconductor device according to a first embodiment;

FIG. 2 is an explanatory diagram of a configuration of a channel film according to the first embodiment;

FIG. 3 is a cross-sectional view for explaining a manufacturing method of a semiconductor device according to the first embodiment;

FIG. 4 is a cross-sectional view for explaining the manufacturing method of a semiconductor device according to the first embodiment;

FIG. 5 is a partial enlarged cross-sectional view for explaining the manufacturing method of a semiconductor device according to the first embodiment;

FIG. 6 is a cross-sectional view for explaining the manufacturing method of a semiconductor device according to the first embodiment;

FIG. 7 is a graph showing a relationship between an absorption coefficient and a frequency;

FIG. 8 is a cross-sectional view for explaining the manufacturing method of a semiconductor device according to the first embodiment;

FIG. 9 is a cross-sectional view for explaining the manufacturing method of a semiconductor device according to the first embodiment;

FIG. 10 is a cross-sectional view showing a schematic configuration of a semiconductor device according to a second embodiment; and

FIGS. 11A to 11D are cross-sectional views for explaining a manufacturing method of a semiconductor device according to the second embodiment.

### DETAILED DESCRIPTION

Embodiments of a semiconductor device and a manufacturing method thereof according to the present invention will now be explained with reference to the accompanying drawings. The present invention is not limited to the embodiments.

In a manufacturing method of a semiconductor device according to an embodiment, a stacked structure constituted by an electrode, an insulation film, and an amorphous thin film is formed. A microwave of a first frequency is irradiated to the stacked structure so as to selectively heat the electrode. Thereby a seed crystal is formed in a part of the amorphous thin film adjacent to the electrode. A microwave of a second frequency that is different from the first frequency is irradiated to the stacked structure so as to grow the seed crystal. Thereby a polycrystalline thin film is formed.

### First Embodiment

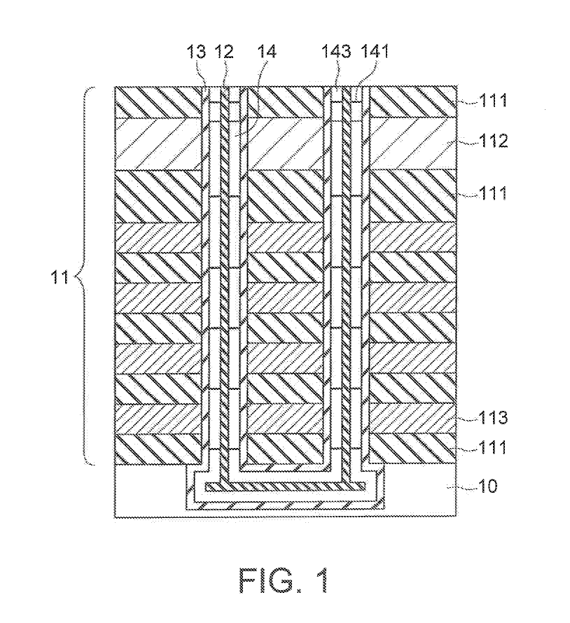

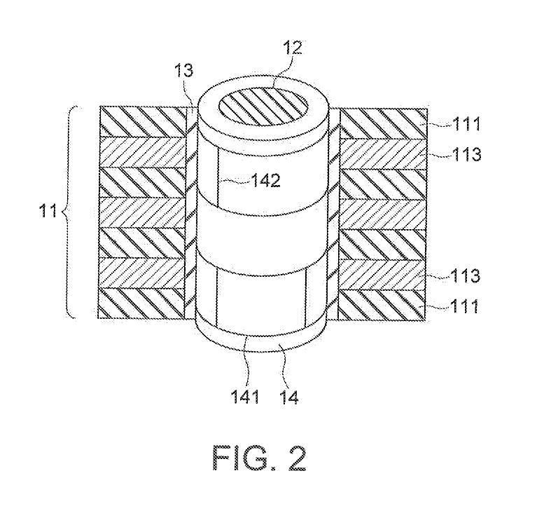

A semiconductor device according to a first embodiment is explained first with reference to FIGS. 1 and 2. The semiconductor device according to the first embodiment is a three-dimensional memory. The three-dimensional memory has a stacked structure in which plane electrodes and an interlayer dielectric film are alternately (vertically) stacked and includes a columnar insulation film that passes through the stacked structure from the top layer to the bottom layer thereof. At an intersection of the plane electrode and the columnar insulation film, a vertical transistor (FET) that functions as a NAND memory cell is formed. As such transistors are serially connected to each other in a stacking direction of the stacked structure, a NAND string is formed. Lower ends of adjacent NAND strings are connected to each other by piping in an electrode layer under the stacked structure.

FIG. 1 is a cross-sectional view showing a schematic configuration of a three-dimensional memory according to the first embodiment. As shown in FIG. 1, the three-dimensional memory includes an electrode layer 10, an interlayer dielectric film 111, a select gate 112, a word line 113, a columnar insulation film 12, a memory insulation film 13, and a channel film 14.

The electrode layer 10 is made of a material such as Si and is formed on a substrate (not shown). The electrode layer 10 functions as a gate electrode of a corresponding transistor. A stacked structure 11 is formed on the electrode layer 10.

The stacked structure 11 is constituted by alternately stacking the interlayer dielectric film 111 and plane electrodes (the select gate 112 and the word line 113). The interlayer dielectric film 111 is arranged on the bottom of the stacked structure 111, that is, on the electrode layer 10. The electrode layer 10 is thereby insulated from the bottom plane electrode (the word line 113). Further, the interlayer dielectric film 111 is arranged on the top of the stacked structure 11. A source line and a bit line (both not shown) are formed on the top interlayer dielectric film 111. The interlayer dielectric film 111 is made of an insulation material such as SiO₂.

The plane electrode is a gate electrode of a vertical transistor that constitutes a NAND string. The top plane electrode is used as the select gate 112 and other plane electrodes are used as the word line 113. The plane electrode is formed on the interlayer dielectric film 111 and is made of a metal material such as W, Cu, and Al.

The columnar insulation film 12 is a columnar insulation film that is formed to pass through the stacked structure 11 from the top layer to the bottom layer thereof. The columnar insulation film 12 is made of an insulation material such as SiO₂ and SiN.

The memory insulation film 13 is formed between the stacked structure 11 and the columnar insulation film 12 vertically along the stacked structure 11 (in a stacking direction of the stacked structure 11), and is a gate dielectric film in a vertical transistor, which constitutes a NAND string. For example, the memory insulation film 13 is made of SiO₂, SiN, and Al₂O₃ to have a stacked structure, thereby being capable of accumulating charges.

The channel film 14 is a polycrystalline Si thin film formed between the columnar insulation film 12 and the memory insulation film 13. The polycrystalline Si thin film is formed of a large number of adjacent Si crystals, and a grain boundary is formed between the Si crystals. The grain boundary in this context means an interface between adjacent Si crystals.

The channel film 14 is not limited to a polycrystalline Si thin film, and the channel film 14 can be arbitrarily selected among polycrystalline thin films made of a Si containing material. For example, the channel film 14 can be a polycrystalline SiGe thin film.

The channel film 14 includes channels adjacent to the respective plane electrodes (the select gate 112 and the word line 113). Each of the channels is a channel for respective transistors constituting a NAND string. A part of the channel film 14 adjacent to each plane electrode, that is, a part of the channel film 14 constituting the same layer as each plane electrode, functions as a channel adjacent to each plane electrode, and this part (channel) is constituted by one or more Si crystals.

FIG. 2 is an explanatory diagram of a configuration of the channel film 14. In FIG. 2, the stacked structure 11 and the memory insulation film 13 are shown in a cross-sectional view, and the channel film 14 is shown in a perspective view. An upper end of the channel film 14 is shown in a cross-sectional view that is vertical to a direction to which the columnar insulation film 12 extends, and cross-sections of the channel film 14 and the columnar insulation film 12 are also shown.

FIG. 2 shows a grain boundary 141 and a grain boundary 142. The grain boundary 141 is a grain boundary between a Si crystal constituting a channel and another Si crystal adjacent to the Si crystal in a direction parallel to the direction to which the columnar insulation film 12 extends. An influence of the grain boundary 141 on a threshold voltage of a transistor is large, so that there is a variation in the threshold voltage between a transistor having the grain boundary 141 in a channel and a transistor not having the grain boundary 141 in a channel.

On the other hand, the grain boundary 142 is a grain boundary between a Si crystal constituting a channel and another Si crystal adjacent to the Si crystal in a direction vertical to the direction to which the columnar insulation film 12 extends (a direction to which a current flows in a channel). An influence of the grain boundary 142 on a threshold voltage of a transistor is small, so that there is a small variation in the threshold voltage between a transistor having the grain boundary 142 in a channel and a transistor not having the grain boundary 142 in a channel.

As shown in FIG. 2, the grain boundary 141 is formed in a part of the channel film 14 adjacent to the interlayer dielectric film 111, that is, in a part of the channel film 14 constituting the same layer as the interlayer dielectric film 111. That is, the grain boundary 141 is formed not inside of a channel but outside thereof. This means that the grain diameter of a Si crystal constituting a channel in a direction parallel to the columnar insulation film 12 is larger than the thickness of the plane electrode.

On the other hand, as shown in FIG. 2, one or more grain boundaries 142 are formed in a part of the channel film 14 adjacent to a plane electrode. A case where a channel is constituted by a plurality of Si crystals means a case where two or more grain boundaries 142 are formed in a part of the channel film 14 adjacent to a plane electrode.

Furthermore, as shown in FIG. 1, a doped area 143 is formed at an upper end of the channel film 14. The doped area 143 is a part having a dopant doped therein. The doped area 143 is connected to a source line and a bit line (both not shown), which are also used as a source electrode and a drain electrode, respectively.

As explained above, in the semiconductor device according to the first embodiment, the grain boundary 141 between Si crystals is formed outside of a channel. That is, the grain boundary 141 that largely influences a threshold voltage is not formed in any one of the channels included in a semiconductor device. Therefore, it is possible to suppress occurrence of a variation in the threshold voltage between respective transistors.

In the semiconductor device according to the first embodiment, a Si crystal constituting a channel has a grain diameter larger than the thickness of a plane electrode. As a result, the channel of the semiconductor device has a large carrier mobility.

In the first embodiment, while a semiconductor device is a pipe-shaped three-dimensional memory, the semiconductor device is not limited thereto. For example, the semiconductor device can be also a linear three-dimensional memory or a three-dimensional memory having a different configuration.

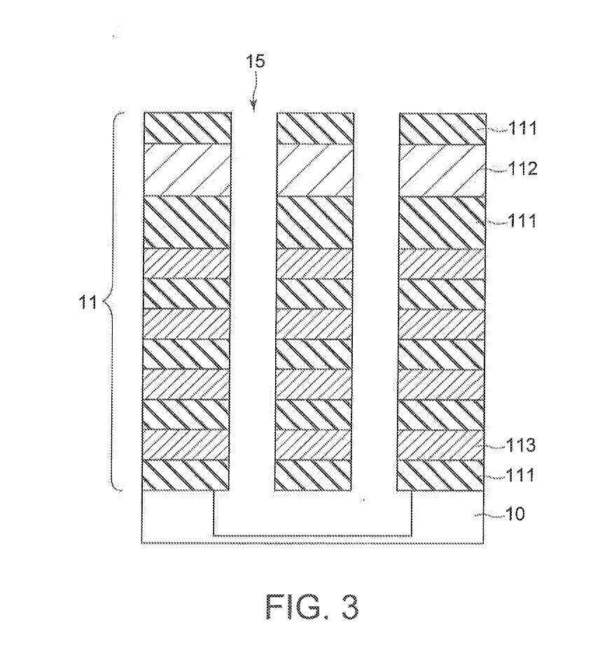

Next, a manufacturing method of a semiconductor device according to the first embodiment is explained with reference to FIGS. 3 to 9.

First, the electrode layer 10 is formed on a substrate (not shown). The interlayer dielectric film 111 and plane electrodes (the select gate 112 and the word line 113) are stacked alternately for a plurality of times on the electrode layer 10, thereby forming the stacked structure 11. A memory hole 15 is formed in the electrode layer 10 and the stacked structure 11 (see FIG. 3).

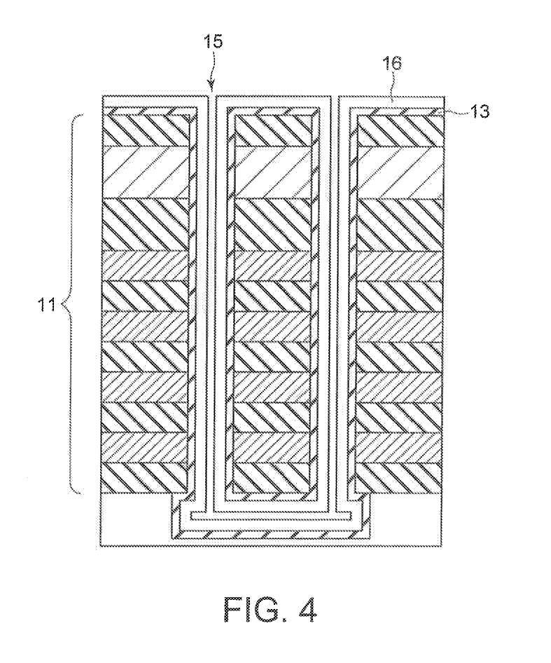

Next, the memory insulation film 13 is formed on the entire surface, that is, on a surface of the stacked structure 11 and an inner wall surface of the memory hole 15. An amorphous Si thin film 16 is further formed on a surface of the memory insulation film 13 (see FIG. 4). The amorphous Si thin film 16 is a non-crystalline thin film made of Si, and the amorphous Si thin film 16 can be formed by CVD using at least one of SiH₄ and Si₂H₆ gases under an atmosphere of 450 to 550° C. For example, the thickness of the amorphous Si thin film 16 is 4 to 10 nm.

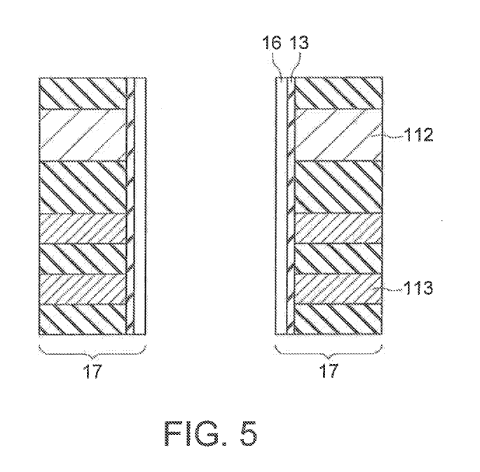

With the processes explained above, as shown in FIG. 5, a stacked structure 17 constituted by plane electrodes (the select gate 112 and the word line 113), the memory insulation film 13, and the amorphous Si thin film 16 is formed on a side surface of the memory hole 15.

Next, a microwave of a first frequency is irradiated to the stacked structure 17. The first frequency is a frequency at which a plane electrode can be selectively heated. That is, the first frequency is a frequency at which a plane electrode can be heated to a desired temperature and the interlayer dielectric film 113 and the amorphous Si thin film 16 are hardly heated.

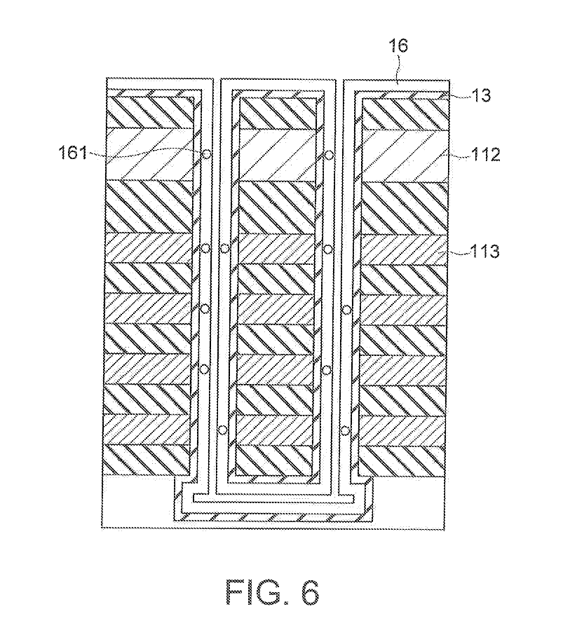

As a microwave of the first frequency is irradiated to a plane electrode so as to selectively heat the plane electrode to 700 to 750° C., a seed crystal 161 is formed in a part of the amorphous Si thin film 16 adjacent to the plane electrode, that is, a part of the amorphous Si thin film 16 that is adjacent to the plane electrode and constitutes the same layer as the plane electrode (see FIG. 6). As a result, a position of the seed crystal 161 can be limited to a part adjacent to a plane electrode. The number of the seed crystals 161 formed in parts adjacent to the respective plane electrodes is arbitrary.

To control the position of the seed crystal 161, the first frequency is preferably a frequency that is hardly absorbed by amorphous Si. This is because, when the first frequency is a frequency that is easily absorbed by amorphous Si, the amorphous Si thin film 16 is heated by irradiation of a microwave, so that the seed crystals 161 are formed at random positions regardless of the positions of the respective plane electrodes.

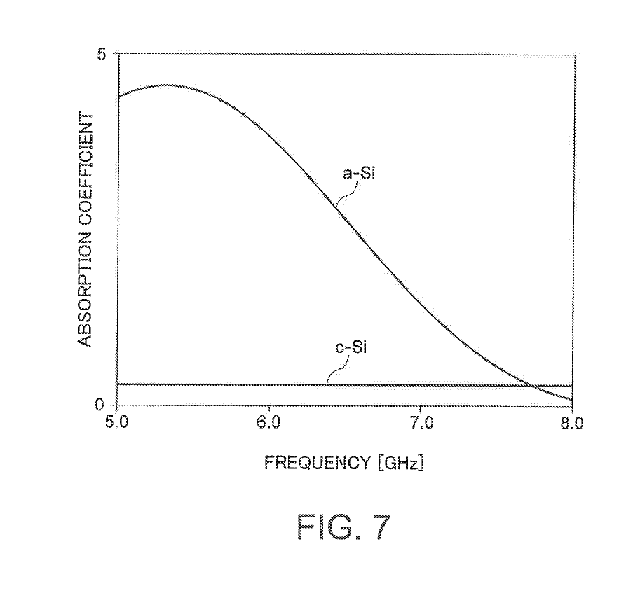

FIG. 7 is a graph showing a relationship between a frequency and an absorption coefficient. In FIG, 7, the vertical axis represents the absorption coefficient and the horizontal axis represents the frequency. As shown in FIG. 7, the absorption coefficient of amorphous Si (a-Si) decreases at a frequency of 8 GHz or higher. Therefore, it is preferable that the first frequency is equal to or higher than 8 GHz, and the first frequency can be, for example, 24.125 GHz.

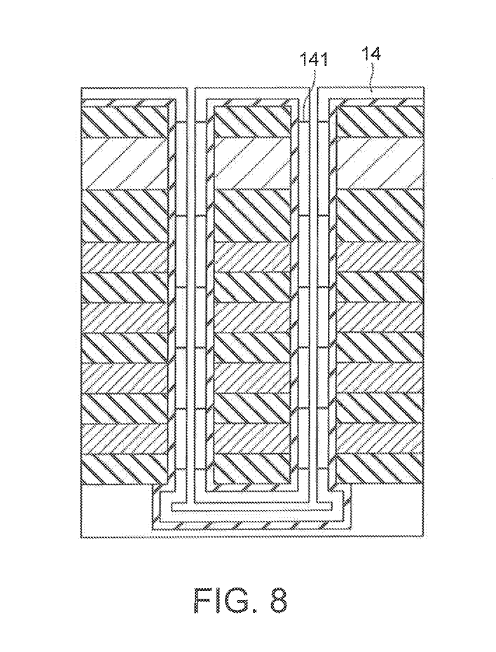

Next, a microwave of a second frequency is irradiated to the stacked structure 17. The second frequency is a frequency at which the seed crystal 161 is grown. By irradiating a microwave of the second frequency to the stacked structure 17 and performing microwave annealing thereon, torsional oscillation occurs in electronic polarization due to an irregular atomic arrangement present in amorphous Si, so that covalent bonds of Si are recombined and positions thereof are slightly moved. Accordingly, a Si crystal is grown from the seed crystal 161 as a starting point at a high speed, and the amorphous Si thin film 16 is changed into a polycrystalline Si thin film (see FIG. 8). The time during which microwave annealing is performed can be arbitrarily set according to the second frequency and the like, and the time is, for example, 5 to 30 minutes. The channel film 14 is formed in this way.

With microwave annealing, a Si crystal is grown from the seed crystal 161 as a starting point. As explained above, because the seed crystal 161 is formed in a part of the amorphous Si thin film 16 adjacent to a plane electrode, a Si crystal is grown from a part of the amorphous Si thin film 16 adjacent to a plane electrode toward a part of the amorphous Si thin film 16 adjacent to the interlayer dielectric film 111 at a substantially constant speed. Accordingly, a Si crystal that is grown from a part adjacent to a plane electrode collides with a Si crystal that is grown from a part adjacent to a plane electrode above (or below) the plane electrode with the interlayer dielectric film 111 being interposed therebetween at a part adjacent to the interlayer dielectric film 111. As a result, the grain boundary 141 between Si crystals adjacent to each other in a direction parallel to the columnar insulation film 12 is formed in a part of the channel film 14 adjacent to the interlayer dielectric film 111, that is, outside of a channel.

In order to grow the seed crystal 161, the second frequency is preferably a frequency that is easily absorbed by a Si crystal (the seed crystal 161), and the second frequency is, for example, lower than 8 GHz. As shown in FIG. 7, because the absorption coefficient of a Si crystal (c-Si) becomes large at 5 to 6 GHz, the second frequency is preferably 5 to 6 GHz, and can be, for example, 5.8 GHz.

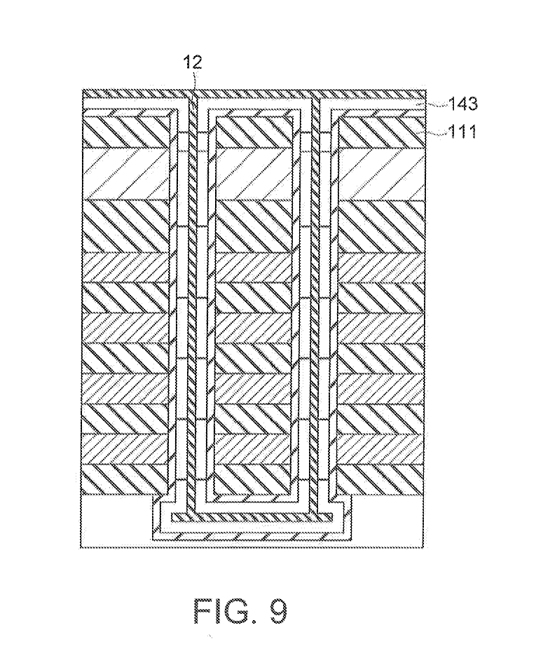

Next, a dopant is doped in the top part of the channel film 14 to form the doped area 143, and an insulation material such as SiO₂ and SiN is stacked to fill the memory hole 15, thereby forming the columnar insulation film 12 (see FIG. 9). Thereafter, a surface of a semiconductor device is removed by RIE (Reactive Ion Etching) and the like until the interlayer dielectric film 111 on the top of the stacked structure 11 is exposed. With this process, the semiconductor device shown in FIG. 1 is formed.

As explained above, according to the manufacturing method of a semiconductor device of the first embodiment, the grain boundary 141 between Si crystals is formed outside of a channel. Therefore, a semiconductor device including a transistor not having the grain boundary 141 in a channel can be formed. Therefore, it is possible to suppress occurrence of a variation in a threshold voltage between a plurality of transistors included in the semiconductor device.

Furthermore, the seed crystal 161 is selectively formed in a part of the amorphous Si thin film 16 adjacent to a plane electrode. A Si crystal is then grown from the seed crystal 161 to a part of the amorphous Si thin film 16 adjacent to the interlayer dielectric film 111. As a result, the grain diameter of a Si crystal that is grown from the seed crystal 161 as a starting point in a direction parallel to the columnar insulation film 12 is larger than the thickness of a plane electrode. With this process, a channel with large carrier mobility can be formed.

Further, by using microwave annealing, a Si crystal can be grown at a high speed. Therefore, the semiconductor device can be manufactured in a short time.

The manufacturing method of a semiconductor device according to the first embodiment can be applied as a manufacturing method of an arbitrary semiconductor device that requires crystallization of amorphous Si, such as a linear three-dimensional memory and a three-dimensional memory with a configuration, which is different from that of the three-dimensional memory shown in FIG. 1. By using the manufacturing method of a semiconductor device according to the first embodiment, the position of a seed crystal and that of a grain boundary can be controlled.

### Second Embodiment

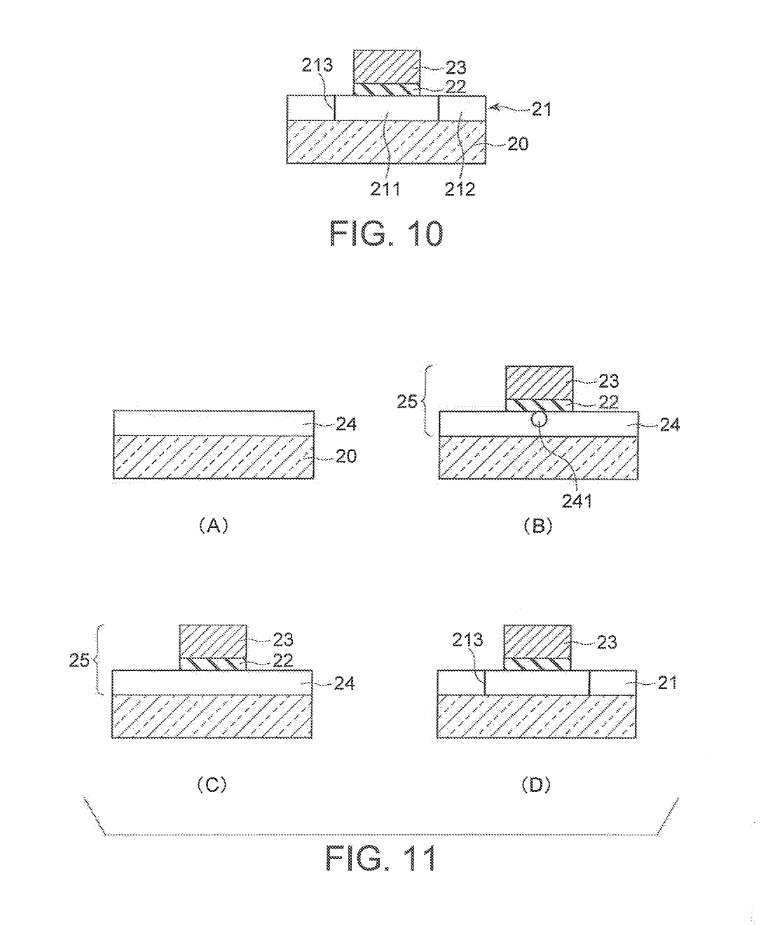

Next, a semiconductor device according to a second embodiment is explained with reference to FIG. 10. The semiconductor device according to the second embodiment is a thin-film transistor (hereinafter, “TFT”) for driving liquid crystals. FIG. 10 is a cross-sectional view showing a schematic configuration of a TFT according to the second embodiment. As shown in FIG. 10, the TFT includes a glass substrate 20, a channel film 21, a gate dielectric film 22, and a gate electrode 23.

The channel film 21 is a polycrystalline SiGe thin film formed on the glass substrate 20, and includes a channel 211 and a doped area 212 having a dopant doped therein. While one channel 211 is formed on the glass substrate 20 in FIG. 10, generally, a plurality of the channels 211 are formed on the glass substrate 20. The same holds true for the gate dielectric film 22 and the gate electrode 23. Details of the channel 211 are explained later.

The gate dielectric film 22 is formed on the channel 211. The gate dielectric film 22 is made of an insulation material such as SiO₂. The gate electrode 23 is formed on the gate dielectric film 22. The gate electrode 23 is made of a metal material such as W, Cu, and Al.

The channel 211 is a channel adjacent to the gate electrode 23. The channel 211 is a part of the channel film 21 adjacent to the gate electrode 23, that is, a part that is below the gate electrode 23, and the part is constituted by one or more SiGe crystals. A grain boundary 213 between a SiGe crystal constituting the channel 211 and another SiGe crystal adjacent to the SiGe crystal in a direction parallel to the glass substrate 20 is formed outside of the channel 211. Therefore, according to the second embodiment, the grain boundary 213 is formed in the doped area 212. This means that the grain diameter of a SiGe crystal constituting the channel 211 in the direction parallel to the glass substrate 20 is larger than the width of the channel 211.

An influence of the grain boundary 213 on a threshold voltage of a transistor is large, so that there is a variation in the threshold voltage between a transistor having the grain boundary 213 in the channel 211 and a transistor not having the grain boundary 213 in the channel 211. However, according to the semiconductor device of the second embodiment, the grain boundary 213 is formed outside of the channel 211. That is, any one of the channels 211 formed on the glass substrate 20 not having the grain boundary 213. Accordingly, the variation in the threshold voltage between the respective transistors can be suppressed.

Furthermore, in the semiconductor device according to the second embodiment, a SiGe crystal constituting a channel has a grain diameter larger than the width of the channel 211. As a result, the channel of the semiconductor device has a large carrier mobility.

The channel film 21 is not limited to a polycrystalline SiGe thin film, and the channel film 21 can be arbitrarily selected among polycrystalline thin films made of a Si containing material. For example, the channel film 21 can be a polycrystalline Si thin film.

A grain boundary between a SiGe crystal constituting the channel 211 and another SiGe crystal adjacent to the SiGe crystal in a direction vertical to the glass substrate 20 may be formed in the channel 211, or formation of the grain boundary may be omitted. In both cases, an influence of the grain boundary on a threshold voltage of a transistor is small, so that, in the semiconductor device according to the second embodiment, the variation in the threshold voltage is suppressed.

Next, a manufacturing method of a semiconductor device according to the second embodiment is explained with reference to FIGS. 11A to 11D. FIGS. 11A to 11D are cross-sectional views for explaining the manufacturing method of a semiconductor device according to the second embodiment.

First, an amorphous SiGe thin film 24 is formed on the glass substrate 20 (see FIG. 11A). The amorphous SiGe thin film 24 is a non-crystalline thin film made of SiGe, and the amorphous SiGe thin film 24 can be formed by CVD using Si₂H₆ and GeH₄ gases under an atmosphere of 450° C. For example, the thickness of the amorphous SiGe thin film 24 is 50 to 100 nm.

Next, the gate dielectric film 22 and the gate electrode 23 are formed on the amorphous SiGe thin film 24 (see FIG. 11B). Respective materials for the gate dielectric film 22 and the gate electrode 23 are deposited on the amorphous SiGe thin film 24 by CVD and the materials are then patterned by etching, thereby forming the gate dielectric film 22 and the gate electrode 23. With the processes explained above, a stacked structure 25 constituted by the gate electrode 23, the gate dielectric film 22, and the amorphous SiGe thin film 24 is formed on the glass substrate 20.

Next, a microwave of a first frequency is irradiated to the stacked structure 25. The first frequency is a frequency at which the gate electrode 23 can be selectively heated. That is, the first frequency is a frequency at which the gate electrode 23 can be heated to a desired temperature and the gate dielectric film 22 and the amorphous SiGe thin film 24 are hardly heated.

A microwave of the first frequency is irradiated to the gate electrode 23 so as to selectively heat the gate electrode 23 to 700 to 750° C., so that a seed crystal 241 is formed in a part of the amorphous SiGe thin film 24 adjacent to the gate electrode 23, that is, in a part of the amorphous SiGe thin film 24 below the gate electrode 23 (see FIG. 11C). As a result, the position of the seed crystal 241 can be controlled to be a part adjacent to the gate electrode 23. The number of the seed crystals 241 formed in parts adjacent to the respective gate electrodes 23 is arbitrary.

In order to control the position of the seed crystal 241, the first frequency is preferably a frequency that is hardly absorbed by amorphous SiGe. This is because, when the first frequency is a frequency that is easily absorbed by amorphous SiGe, the amorphous SiGe thin film 24 is heated by irradiation of a microwave, so that the seed crystals 241 are formed at random positions regardless of the positions of the respective gate electrodes 23. It is conceivable that absorption coefficients of Si and SiGe microwaves are relatively close to each other. Therefore, similarly to the first embodiment, it is preferable the first frequency is equal to or higher than 8 GHz, and the first frequency can be, for example, 24.125 GHz.

Next, a microwave of a second frequency is irradiated to the stacked structure 25. The second frequency is a frequency at which the seed crystal 241 is grown. By irradiating a microwave of the second frequency to the stacked structure 25 to perform microwave annealing thereon, a SiGe crystal is grown from the seed crystal 241 as a starting point at a high speed and the amorphous SiGe thin film 24 is changed into a polycrystalline SiGe thin film (see FIG. 11D). The time during which microwave annealing is performed can be arbitrarily set according to the second frequency and the like, and the time is, for example, 5 to 30 minutes. The channel film 21 is formed in this way.

With microwave annealing, a SiGe crystal is grown from the seed crystal 241 as a starting point, As explained above, because the seed crystal 241 is formed in a part of the amorphous SiGe thin film 24 adjacent to the gate electrode 23, a SiGe crystal is grown from a part of the amorphous SiGe thin film 24 adjacent to the gate electrode 23 toward outside thereof. Accordingly, as microwave annealing ends when a SiGe crystal has been grown to outside of a part of the amorphous SiGe thin film 24 adjacent to the gate electrode 23, the grain boundary 213 can be formed outside of the channel 211.

In order to grow the seed crystal 241, the second frequency is preferably a frequency that is easily absorbed by a SiGe crystal (the seed crystal 241), and for example, lower than 8 GHz. Similarly to the first embodiment, the second frequency is preferably 5 to 6 GHz, and can be, for example, 5.8 GHz.

Next, a dopant is doped in the channel film 21 to form the doped area 212, so that the semiconductor device shown in FIG. 10 is formed. Because the gate electrode 23 is formed, a dopant is not doped in a part of the channel film 21 below the gate electrode 23, this part becomes the channel 211, and an outside part thereof becomes the doped area 212.

As explained above, according to the manufacturing method of a semiconductor device of the second embodiment, the grain boundary 213 between SiGe crystals is formed outside of the channel 211. In this manner, a semiconductor device that does not have the grain boundary 213 in a channel can be formed. As a result, it is possible to suppress occurrence of a variation in a threshold voltage between a plurality of transistors included in the semiconductor device.

The seed crystal 241 is selectively formed in a part of the amorphous SiGe thin film 24 adjacent to the gate electrode 23. As a result, the grain diameter of a SiGe crystal that is grown from the seed crystal 241 as a starting point in a direction parallel to the glass substrate 20 is larger than the width of the channel 211. Accordingly, the channel 211 with a large carrier mobility can be formed.

Furthermore, by using microwave annealing, a SiGe crystal can be grown at a high speed. Therefore, the semiconductor device can be manufactured in a short time.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of semiconductor device comprising:
forming a stacked structure constituted by an electrode, an insulation film, and an amorphous thin film;
forming a seed crystal in part of the amorphous thin film adjacent to the electrode by irradiating a microwave of a first frequency to the stacked structure so as to selectively heat the electrode; and
forming a polycrystalline thin film by irradiating a microwave of a second frequency that is different from the first frequency to the stacked structure so as to grow the seed crystal.

2. The method of claim 1, wherein the first frequency is equal to or higher than 8 GHz, and the second frequency is lower than 8 GHz.

3. The method of claim 1, wherein the first frequency is 24.125 GHz.

4. The method of claim 1, wherein the second frequency is 5.8 GHz.

5. The method of claim 1, wherein the amorphous thin film is made of a Si containing material.

6. The method of claim 1, wherein the amorphous thin film is an amorphous Si thin film or an amorphous SiGe thin film.

7. The method of claim 1, wherein the amorphous thin film is formed by CVD.

8. The method of claim 1, wherein the electrode is selectively heated to equal to or higher than 700° C. and to equal to or lower than 750° C. by the microwave of the first frequency.

9. The method of claim 1, wherein the electrode is made of a metal material.

10. The method of claim 1, wherein the electrode is made of W, Cu, or Al.

11. A semiconductor device comprising:
a stacked structure constituted by electrodes and interlayer dielectric films stacked alternately and vertically, at least one of the electrodes is a select gate;
a columnar insulation film vertically passing though the stacked structure;
an insulation film vertically along the stacked structure; and
a channel film that is a polycrystalline thin film between the insulation film and the columnar insulation film and that includes a channel adjacent to the select gate, wherein
the channel is constituted by one or more crystals, and
a grain boundary between the crystal constituting the channel and another crystal adjacent to the crystal in a direction parallel to the columnar insulation film is formed outside of the channel.

12. The device of claim 11, wherein the crystal constituting the channel has a grain diameter larger than a thickness of the electrode adjacent to the channel via the insulation film.

13. The device of claim 11, wherein the channel film is a polycrystalline thin film made of a Si containing material.

14. The device of claim 11, wherein the channel film is a polycrystalline Si thin film.

15. The device of claim 11, wherein the channel film has a dopant doped area.

16. A semiconductor device comprising:
a substrate;
a channel film that is a polycrystalline thin film on the substrate and includes a channel constituted by one or more crystals;
an insulation film on the channel; and
an electrode on the insulation film, wherein
a grain boundary between the crystal constituting the channel and another crystal adjacent to the crystal in a direction parallel to the substrate is formed outside of the channel.

17. The device of claim 16, wherein the channel film is a polycrystalline thin film made of a Si containing material.

18. The device of claim 16, wherein the channel film is a polycrystalline SiGe thin film.

19. The device of claim 16, wherein the channel film has a dopant doped area.
